(19) United States
(12) Patent Application Publication
(10) Pub. No.: US 2026/0148927 A1
(43) Pub. Date: May 28, 2026

(54) MULTIPLE CHARGED-PARTICLE BEAM IRRADIATION APPARATUS, MULTIPLE CHARGED-PARTICLE BEAM IRRADIATION METHOD, CORRECTION MAP GENERATION APPARATUS, AND CORRECTION MAP GENERATION METHOD

(71) Applicant: NuFlare Technology, Inc., Yokohama-shi (JP)

(72) Inventors: Yuji FUJIWARA, Yokohama-shi (JP); Yasuo KATO, Yokohama-shi (JP); Hiroshi MATSUMOTO, Yokohama-shi (JP)

(73) Assignee: NuFlare Technology, Inc., Yokohama-shi (JP)

(21) Appl. No.: 19/352,569

(22) Filed: Oct. 8, 2025

(30) Foreign Application Priority Data
Nov. 26, 2024 (JP) 2024-205634

(51) Int. Cl. H01J 37/24; H01J 37/22

(52) U.S. Cl. CPC H01J 37/243; H01J 37/22; H01J 2237/24514; H01J 2237/30455

(57) ABSTRACT

In one embodiment, a multiple charged-particle beam irradiation apparatus includes a correction map generation unit calculating, for each pixel, a beam modulation rate for the pixel and a beam modulation rate for at least one of pixels surrounding the pixel, based on an amount of displacement of a beam emitted toward the pixel and a position of a pattern placed within the pixel and generating a correction map in which modulation rates are defined, and an irradiation dose correction unit calculating, for each pixel, a corrected irradiation dose by adding a value obtained by multiplying the beam modulation rate for the pixel defined in the correction map by the beam irradiation dose for the pixel and a value obtained by multiplying the beam modulation rate for the at least one pixel by a beam irradiation dose for a pixel serving as an associated destination of the at least one pixel.

### CROSS REFERENCE TO RELATED APPLICATION

This application is based upon and claims benefit of priority from the Japanese Patent Application No. 2024-205634, filed on Nov. 26, 2024, the entire contents of which are incorporated herein by reference.

### FIELD

The present invention relates to a multiple charged-particle beam irradiation apparatus, a multiple charged-particle beam irradiation method, a correction map generation apparatus, and a correction map generation method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

A writing apparatus that uses a multi-beam can emit many beams at one time, as compared to when writing is performed with a single electron beam, thus the throughput can be significantly improved. As a form of multi-beam writing apparatus, a multi-beam writing apparatus using a blanking aperture array substrate forms multi-beam (a plurality of electron beams) by passing an electron beam emitted from e.g., an electron gun through a shaping aperture array member having a plurality of openings. The multi-beam passes through the corresponding blankers in the blanking aperture array substrate. The blanking aperture array substrate includes electrode pairs (blankers) each for individually deflecting a beam in the multi-beam, and openings for beam passage each formed between an electrode pair. The blanking aperture array substrate controls the electrode pairs corresponding to the beams in the multi-beam at the same potential or different potentials, thereby performing blanking deflection of the passing beam. An electron beam deflected by a blanker is blocked, and an electron beam not deflected by a blanker is irradiated onto a substrate.

In multi-beam writing, beam displacement may occur due to, for example, distortion of the optical system, deviation from the designed values of the shaping aperture array that forms multiple beams, and the Coulomb interaction. There are problems in that when constituent beams of the multiple beams are displaced, a pattern is written with displacement and critical dimension (CD) deviation. Thus, it is desirable to correct the displacement and CD deviation of the pattern formed by irradiation with displaced beams.

In Japanese Unexamined Patent Application Publication No. 2016-119423, a modulation rate map in which post-distribution modulation rates are defined for the respective pixels and in which modulation rates indicating the relation to the distribution source are defined for the surrounding pixels is generated in addition to an irradiation dose map (bit map), corrected irradiation doses are acquired by combining the irradiation dose map and the modulation rate map, and the displacement and CD deviation of a pattern formed by irradiation with multiple beams including displaced beams are corrected by irradiating corresponding pixels with beams with the corrected irradiation doses.

FIGS. 10 and 11 illustrate examples of irradiation dose distribution to correct displacement and CD deviation using the existing method described above. As illustrated in FIG. 10, in a case where the pattern edges align with the pixel boundaries (i.e., under on-grid conditions), the irradiation dose for a 3×3 pixel pattern is distributed to a 4×4 pixel region. In contrast, as illustrated in FIG. 11, in a case where the pattern edges do not align with the pixel boundaries (i.e., under off-grid conditions), the irradiation dose for a 3×3 pixel pattern is distributed to a 5×5 pixel region. In this manner, there is a problem in that edge resolution may be degraded due to unnecessary irradiation dose distribution.

### BRIEF DESCRIPTION OF THE DRAWINGS

FIG. 1 is a schematic diagram of the configuration of a writing apparatus according to an embodiment of the present invention.

FIG. 2 is a plan view of a shaping aperture array substrate.

FIG. 3 is a diagram for describing an example of a writing operation.

FIG. 4 is a flowchart for describing a writing method according to the same embodiment.

FIG. 5 is a diagram illustrating displacement correction according to a comparative example.

FIGS. 6A and 6B are diagrams illustrating examples of shifts in the amount of displacement.

FIG. 7 is a diagram illustrating displacement correction according to the same embodiment.

FIGS. 8A and 8B are diagrams illustrating examples of shifts in the amount of displacement.

FIGS. 9A and 9B are diagrams illustrating examples of shifts in the amount of displacement.

FIG. 10 is a diagram illustrating an example of irradiation dose distribution.

FIG. 11 is a diagram illustrating an example of irradiation dose distribution.

### DETAILED DESCRIPTION

In one embodiment, a multiple charged-particle beam irradiation apparatus includes a correction map generation unit that calculates, for each pixel serving as an irradiation unit region per beam of multiple charge-particle beams, a beam modulation rate for the pixel and a beam modulation rate for at least one of pixels surrounding the pixel, based on an amount of displacement of a beam emitted toward the pixel and a position of a pattern placed within the pixel to correct, by modulating a beam irradiation dose for the pixel and a beam irradiation dose for the at least one of the pixels surrounding the pixel, a displacement of a pattern formed by a beam that is emitted toward the pixel but displaced, and generates a correction map in which modulation rates are defined for an irradiation region to be irradiated with multiple charge-particle beams such that the calculated beam modulation rate for the pixel is defined at a position of the pixel, and the beam modulation rate for the at least one of the pixels surrounding the pixel is associated with the pixel and defined at a position of the at least one of the pixels surrounding the pixel, a shot data generation unit that calculates, for each pixel, a beam irradiation dose for the pixel, an irradiation dose correction unit that calculates, for each pixel, a corrected irradiation dose by adding a value obtained by multiplying the beam modulation rate for the pixel defined in the correction map by the beam irradiation dose for the pixel and a value obtained by multiplying the beam modulation rate for the at least one pixel, which is defined at the position of the pixel as the at least one of the surrounding pixels in the correction map, by a beam irradiation dose for a pixel serving as an associated destination of the at least one pixel, and an irradiation unit that irradiates a sample surface with multiple charged-particle beams such that corresponding pixels are irradiated with beams with the corrected irradiation doses in a respective manner.

Hereinafter, an embodiment of the present invention will be described based on the drawings.

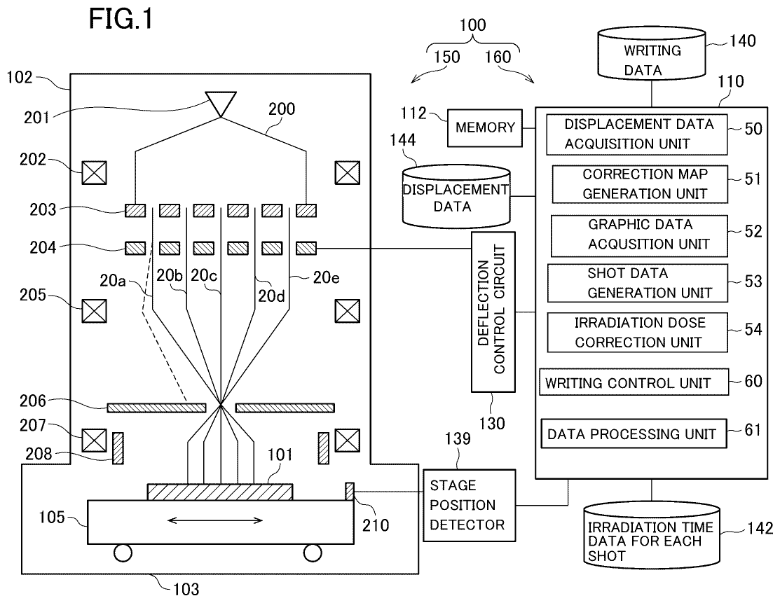

As illustrated in FIG. 1, a writing apparatus 100 according to an embodiment includes a writing unit 150 and a control unit 160. The writing apparatus 100 is an example of a multiple charged-particle beam writing apparatus. The writing unit 150 includes an electron-optical column 102 and a writing chamber 103. In the electron-optical column 102, an electron source 201, an illumination lens 202, a shaping aperture array substrate 203, a blanking aperture array substrate 204, a reduction lens 205, a limiting aperture member 206, an objective lens 207, and a deflector 208 are arranged.

In the writing chamber 103, an XY stage 105 is arranged. On the XY stage 105, a sample 101 is arranged. The sample 101 is, for example, a mask blank serving as a writing target substrate. Examples of the sample 101 include a mask for exposure when manufacturing semiconductor devices or a semiconductor substrate (silicon wafer) on which semiconductor devices are to be manufactured. On the XY stage 105, a mirror 210 for measuring the position of the XY stage 105 is further arranged.

The control unit 160 has a control computer 110, a memory 112, a deflection control circuit 130, a stage position detector 139, and memory devices 140, 142, and 144, such as magnetic disk devices. The control computer 110, the memory 112, the deflection control circuit 130, the stage position detector 139, and the memory devices 140, 142, and 144 are connected to each other via a bus that is not illustrated. Writing data is input from the outside and stored in the memory device 140 (a storage unit).

The control computer 110 has a displacement data acquisition unit 50, a correction map generation unit 51, a graphic data acquisition unit 52, a shot data generation unit 53, an irradiation dose correction unit 54, a writing control unit 60, and a data processing unit 61. The function of each unit of the control computer 110 may be configured using hardware, such as electrical circuits, or software, such as a program that executes these functions. Information input to and output from the various units of the control computer 110 and information during calculations are stored in memory 112 as the need arises.

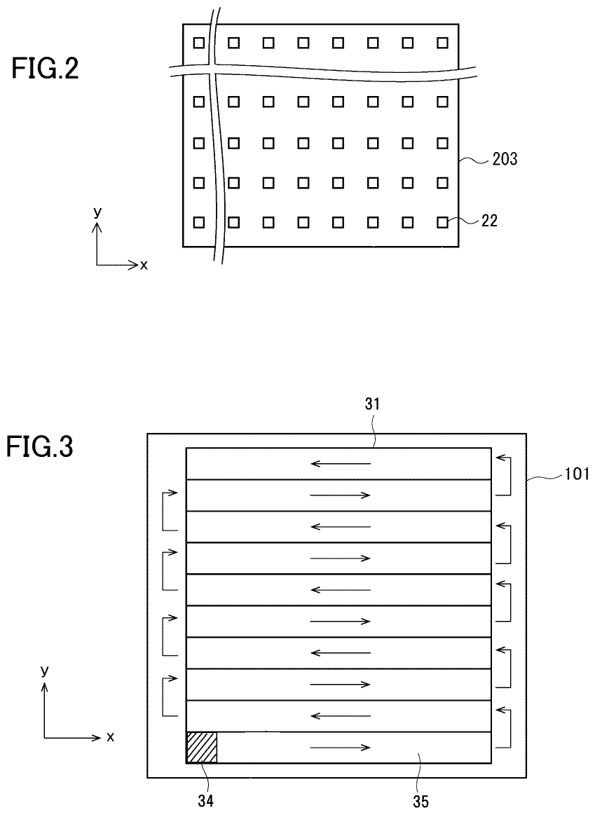

FIG. 2 is a conceptual diagram illustrating the configuration of the shaping aperture array substrate 203. The shaping aperture array substrate 203 has a matrix of multiple apertures 22, arranged vertically (in the y-direction) and horizontally (in the x-direction) and formed with a predetermined array pitch. For example, 512×512 apertures 22 arranged vertically and horizontally are formed. Each aperture 22 is formed, for example, in a rectangular or circular shape with the same dimensions.

The blanking aperture array substrate 204 has passage apertures formed so as to be aligned with the arrangement positions of the apertures 22 of the shaping aperture array substrate 203. A set of two electrodes serving as a pair (a blanker: a blanking deflector) is arranged in each passage aperture. One of the two electrodes for each beam is connected to an amplifier that applies a voltage and the other is grounded. The electron beams passing through the respective passage apertures are deflected independently of each other by the voltages applied by the pairs of two electrodes. Through this electron beam deflection, blanking control is performed.

Next, the operation of the writing unit 150 in the writing apparatus 100 will be described. An electron beam 200 emitted from the electron source 201 (an emission unit) is caused to illuminate the entirety of the shaping aperture array substrate 203 almost vertically by the illumination lens 202. The electron beam 200 passes through the multiple apertures 22 of the shaping aperture array substrate 203, so that multiple beams made up of individual beams 20a to 20e are formed. The beam array shape of the multiple beams is, for example, rectangular. The individual beams, which are the multiple beams, pass through the corresponding blankers of the blanking aperture array substrate 204. The blankers deflect the respective individual beams that pass therethrough.

The multiple beams that have passed through the blanking aperture array substrate 204 are reduced by the reduction lens 205 and proceed toward the central aperture formed in the limiting aperture member 206. Each individual beam deflected by the corresponding blanker of the blanking aperture array substrate 204 is displaced from the central aperture of the limiting aperture member 206 and is shielded by the limiting aperture member 206. In contrast, each individual beam that is not deflected by the corresponding blanker passes through the central aperture of the limiting aperture member 206.

In this manner, the limiting aperture member 206 shields the individual beams that are deflected by the corresponding blankers so as to be in a beam-off state. The beams that are formed from when the beams are switched on until the beams are switched off and that pass through the limiting aperture member 206 constitute the beams for a single shot.

The multiple beams that have passed through the limiting aperture member 206 are focused by the objective lens 207 to form a pattern image having a desired reduction ratio and are deflected in a collective manner by the deflector 208. The sample 101 is irradiated with the deflected beams. For example, when the XY stage 105 is moving continuously, the deflector 208 performs tracking control such that the beam irradiation positions follow the movement of the XY stage 105. The mirror 210 on the XY stage 105 is irradiated with a laser from the stage position detector 139, and the position of the XY stage 105 is measured using the reflected light.

Ideally, the multiple beams with which irradiation is performed at once are aligned at a pitch obtained by multiplying the array pitch of the multiple apertures 22 of the shaping aperture array substrate 203 by the desired reduction ratio described above. The writing apparatus 100 performs a writing operation using a raster scan method, in which irradiation with shot beams is continuously performed in sequence. In a case where the writing apparatus 100 writes a desired pattern, necessary beams are controlled to be switched on through the blanking control in accordance with the pattern.

As illustrated in FIG. 3, a writing region 31 of the sample 101 is virtually divided into multiple stripe regions 35 that are, for example, strips with a predetermined width in the y-direction. For example, the XY stage 105 is moved and adjusted so that an irradiation region 34, which can be irradiated through a single multi-beam irradiation, is positioned at the left end of the first stripe region 35, and writing is started. By moving the XY stage 105 in the −x direction, the writing can proceed in the +x direction relatively.

After completing the writing of the first stripe region 35, the stage position is moved in the −y direction and adjusted so that an irradiation region is positioned at the right end of the second stripe region 35, and then writing is started. Then, by moving the XY stage 105 in the +x direction, for example, the writing is performed in the −x direction.

The third stripe region 35 is written in the +x direction, and the fourth stripe region 35 is written in the −x direction. In this manner, the writing time can be reduced by alternately changing the writing direction. Note that the writing is not limited to that performed by alternately changing the writing direction. The writing may also proceed in the same direction when each of the stripe regions 35 is written.

The stripe region 35 is virtually divided into multiple mesh regions (pixels). The size of each mesh region (pixels) is about the size of a beam, for example. The mesh region (pixels) is the irradiation unit region per individual beam of the multiple beams.

When writing the sample 101 using the multiple beams, as described above, pixels are successively irradiated one pixel at a time in sequence with the multiple beams serving as a shot beam by moving the beam deflection positions using the deflector 208 while following the movement of the XY stage 105 during the tracking operation. The writing sequence determines which pixel on the sample 101 is irradiated with which beam of the multiple beams.

Using the beam pitch between adjacent beams in the x- and y-directions of the multiple beams, the region in which adjacent beams in the x- and y-directions have a region obtained by multiplying the beam pitch (the x-direction) by the beam pitch (the y-direction) therebetween on the surface of the sample 101 is formed by an n×n pixel region (sub-pitch region). For example, in a case where the XY stage 105 moves by the beam pitch (the x-direction) in the −x direction in one tracking operation, n pixels are written by one beam while shifting the irradiation position in the x- or y-direction (or diagonal direction). Other n pixels in the same n×n pixel region are similarly written by a different beam from the one described above in the next tracking operation. In this manner, n pixels are written in each of the n tracking operations using different respective beams, so that all pixels in a single n×n pixel region are written. The same operation is performed for the other n×n pixel regions within the irradiation region for the multiple beams, and the pattern is written.

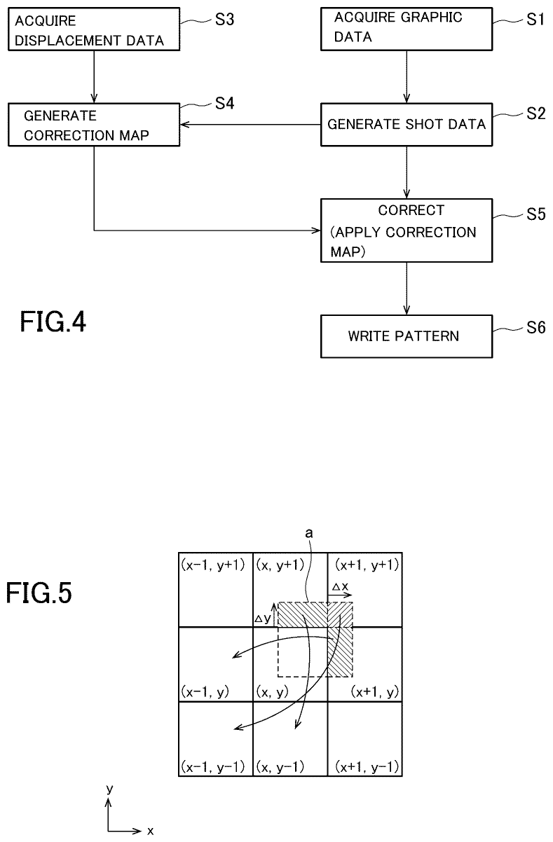

FIG. 4 is a flowchart illustrating a writing method according to the present embodiment. This writing method has a graphic data acquisition process (S1), a shot data generation process (S2), a displacement data acquisition process (S3), a correction map generation process (S4), a correction process (S5), and a writing process (S6).

Before performing the writing process, the amount of beam displacement at each pixel when the surface of the sample 101 is irradiated with multiple beams is measured in advance. It is sufficient that a measurement substrate on which resist has been applied be placed on the stage 105 and irradiated with multiple beams, and the irradiated positions be measured. For example, it is sufficient to write one pixel at a time along the writing sequence, or multiple pixels that are far enough from each other to not cause measurement problems, and then measure the beam irradiation positions of the pixels on the measurement substrate using a position measuring device. For each pixel, the amount of beam displacement can be measured by obtaining the difference between the design position and the measured position. This operation is repeated to measure the amounts of beam displacement for all pixels. Alternatively, the amounts of beam displacement may be determined for all pixels by measuring the amount of displacement of each beam and assigning the corresponding amount of beam displacement to each pixel. The obtained displacement data is input from the outside and stored in the memory device 144.

In the graphic data acquisition process (S1), the graphic data acquisition unit 52 reads out and acquires writing data (graphic data) from the memory device 140. The graphic data acquisition unit 52 reads out, for each stripe region, the corresponding writing data from the memory device 140, for example.

In the shot data generation process (S2), the shot data generation unit 53 inputs writing data and calculates, for each pixel or each group of multiple pixels, the area density of a pattern placed inside the pixel or the group of multiple pixels. For example, the shot data generation unit 53 assigns multiple graphic patterns defined in the writing data to the corresponding pixels. The shot data generation unit 53 then calculates, for each pixel or each group of multiple pixels, the area density of the graphic pattern placed in the pixel or the group of multiple pixels.

The shot data generation unit 53 calculates, for each pixel, the beam irradiation dose for the pixel. For example, the beam irradiation dose for each pixel is calculated by multiplying the pattern area density by the reference irradiation dose. The multiple pixels for which irradiation doses are defined and the multiple mesh regions for which pattern area densities are defined may be the same or different in size. When they are different in size, it is sufficient that each irradiation dose be obtained after interpolating the area density using linear interpolation or the like. Irradiation time can be defined by the value that is obtained by dividing the irradiation dose by the current density.

In the displacement data acquisition process (S3), the displacement data acquisition unit 50 reads out the displacement data stored in the memory device 144 and inputs (acquires) the amount of displacement for each pixel.

In the correction map generation process (S4), the correction map generation unit 51 calculates, for each pixel, the beam modulation rate for the pixel and the beam modulation rate for at least one of the pixels surrounding the pixel to correct the displacement and critical dimension (CD) deviation of the pattern formed by the displaced beam with which the pixel is irradiated. The correction is performed by modulating the beam irradiation dose for the pixel and the beam irradiation dose for the at least one of the pixels surrounding the pixel. The correction map generation unit 51 then generates and outputs a modulation rate map (correction map) in which the modulation rates are defined for the writing region to be written by the multiple beams. In the modulation rate map, for each pixel, the calculated beam modulation rate for the pixel is defined at the position of the pixel, and a calculated beam distribution amount (modulation rate) for at least one pixel to be the destination target among the pixels surrounding the pixel is defined, in relation to the pixel, at the position of the at least one pixel to be the destination target among the pixels surrounding the pixel.

FIG. 5 is a diagram for describing a displacement correction method. FIG. 5 illustrates a case where a beam a, which is emitted toward a pixel at coordinates (x, y), is displaced by Δx in the x-direction and Δy in the y-direction. To correct the displacement of the pattern formed by the displaced beam a to the position that fits the pixel at coordinates (x, y), the irradiation dose for the displacement is distributed to pixels on the opposite side of the pixel from the pixels to which the beam a is displaced in the vicinity of the pixel. In the example in FIG. 5, the irradiation dose that is displaced to the pixel at coordinates (x, y+1) is distributed to the pixel at coordinates (x, y−1). The irradiation dose that is displaced to the pixel at coordinates (x+1, y) is distributed to the pixel at coordinates (x−1, y). The irradiation dose that is displaced to the pixel at coordinates (x+1, y+1) is distributed to the pixel at coordinates (x−1, y−1).

For each surrounding pixel to which the beam is displaced and with which the beam partially overlaps, the ratio obtained by dividing the displaced area (the area of the beam portion that overlaps) by the beam area is calculated as the distribution amount (beam modulation rate) to the pixel located on the opposite side from the pixel that overlaps.

For example, in the example in FIG. 5, in a case where the pixel size (beam size) is set to 1, the area of the portion displaced to the pixel at the coordinates (x+1, y+1) is Δx×Δy. The area of the portion displaced to the pixel at the coordinates (x, y+1) is (1−Δx)×Δy. The area of the portion displaced to the pixel at the coordinates (x+1, y) is Δx×(1−Δy). The area of the portion remaining in the pixel at the coordinates (x, y) is (1−Δx)×(1−Δy).

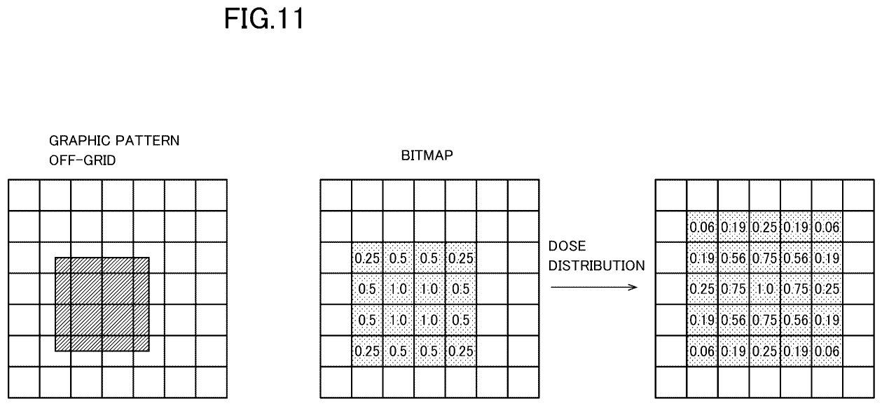

Note that, in the example in FIG. 5, the beam irradiation doses (modulation rates) to be distributed to the surrounding pixels are calculated based only on the amounts of beam displacement, without considering the edge positions of the actual pattern to be written. As a result, the beam irradiation dose may be distributed to the surrounding pixels more than necessary, which may degrade edge resolution (see FIG. 11).

Thus, in the present embodiment, the centroid position of a pattern within a pixel is calculated as edge position information, and the amount of displacement of the centroid position of the pattern within the pixel from the pixel center is obtained. Then, by shifting the amount of beam displacement by the amount of displacement of the centroid position, the modulation rate is calculated considering the edge positions.

The correction map generation unit 51 uses a beam irradiation dose d calculated for each pixel in the shot data generation process to calculate, for the pixel, a centroid position (x′_{g}, y′_{g}) of the pattern within the pixel. As an example of the calculation method, in a case where the right edge of the pattern is present in the pixel, the centroid position can be obtained by x′_{g}=dₓ/2. In a case where the left edge of the pattern is present in the pixel, the centroid position can be obtained by x′_{g}=1−dₓ/2. In a case where the top edge of the pattern is present in the pixel, the centroid position can be obtained by y′_{g}=d_{y}/2. In a case where the bottom edge of the pattern is present in the pixel, the centroid position can be obtained by y′_{g}=1−d_{y}/2. In this case, dₓ is the x-directional contribution to the beam irradiation dose, d_{y} is the y-directional contribution to the beam irradiation dose, and dₓ×d_{y}=d. The method for calculating, from the beam irradiation dose d for each pixel, the centroid position of the pattern within the pixel is not limited to this, and other calculation methods, such as approximating dₓ=d_{y}=√d, may be used to determine the centroid position of the pattern within the pixel.

Regarding the centroid position (x′_{g}, y′_{g}), assume that the bottom-left corner of the pixel is set to the origin (0, 0) and each of the x-direction size and y-direction size of the pixel is set to 1. The beam irradiation dose d is a value in the range 0≤d≤1 and corresponds to the pattern area density to be multiplied by the reference irradiation dose. In a case where the beam irradiation dose d=1, the pattern occupies this entire pixel. In a case where the beam irradiation dose d=0, there is no pattern within this pixel.

In a case where the beam irradiation dose d is 0<d<1, at least one of the top, bottom, left, or right edge exists in the pixel. Which of the top, bottom, left, or right edges of the pattern is present in the pixel can be determined from the beam irradiation doses of pixels surrounding the pixel. For example, in a case where the beam irradiation dose for the pixel located to the left, top-left, or bottom-left of the target pixel for calculation is 1, the target pixel for calculation has the right edge of the pattern. In a case where the beam irradiation dose for the pixel located to the bottom-left, directly below, or to the bottom-right of the target pixel for calculation is 1, the target pixel for calculation has the top edge of the pattern.

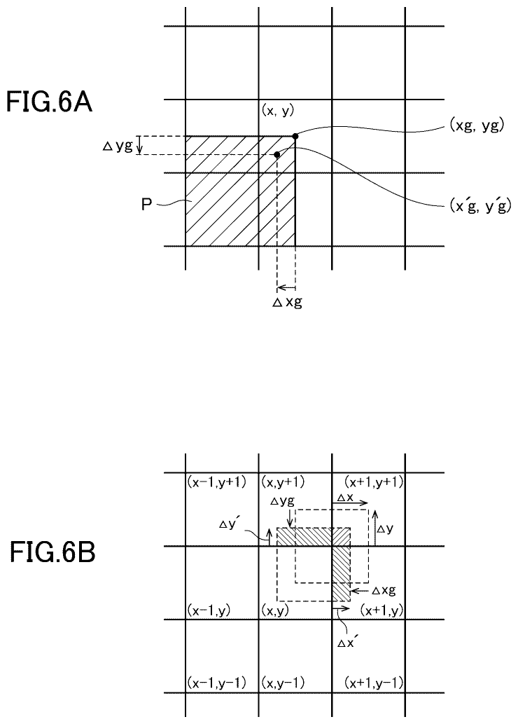

For example, in a case where a graphic pattern P is placed as illustrated in FIG. 6A, the correction map generation unit 51 calculates, for the pixel at the coordinates (x, y), the amount of displacement of the centroid position Δx_{g} in the x-direction and the amount of displacement of the centroid position Δy_{g} in the y-direction for the centroid position (x′_{g}, y′_{g}) of the pattern within the pixel when viewed from the pixel center position (x_{g}, y_{g}).

Instead of the amounts of displacement Δx and Δy of the beam a with which the pixel at the coordinates (x, y) illustrated in the example in FIG. 5 is irradiated, the correction map generation unit 51 shifts the amount of beam displacement by the amount of displacement of the centroid position as illustrated in FIG. 6B. The amounts of beam displacement Δx′ and Δy′ after the shift are as follows.

$$Δ {x}^{′} = Δ x + Δ {x}_{g}$$

$$Δ {y}^{′} = Δ y + Δ {y}_{g}$$

By shifting the amount of beam displacement by the amount of displacement of the centroid position, this may cause excessive or negative distribution of irradiation dose. Thus, the correction map generation unit 51 introduces the following limiter to perform processing such that the amounts of beam displacement Δx′ and Δy′ are to be smaller than the amounts of beam displacement Δx″ and Δy″ having geometrically valid values.

$$Δ {x}^{′′} = min ( max ( Δ {x}^{′} , 0 ) , 1 )$$

$$Δ {y}^{′′} = min ( max ( Δ {y}^{′} , 0 ) , 1 )$$

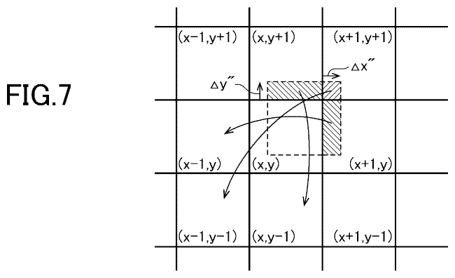

As illustrated in FIG. 7, the correction map generation unit 51 uses the amounts of beam displacement Δx″ and Δy″ to calculate beam irradiation doses (modulation rates) to be distributed to surrounding pixels.

For example, in the example in FIG. 7, the area of the portion displaced to the pixel at the coordinates (x+1, y+1) is Δx″×Δy″. From this value, the amount of distribution (beam modulation rate) to be distributed to the pixel at the coordinates (x−1, y−1) for correction is obtained.

Similarly, the area of the portion displaced to the pixel at the coordinates (x, y+1) is (1−Δx″)×Δy″. From this value, the amount of distribution (beam modulation rate) to be distributed to the pixel at the coordinates (x, y−1) for correction is obtained.

The area of the portion displaced to the pixel at the coordinates (x+1, y) is Δx″×(1−Δy″). From this value, the amount of distribution (beam modulation rate) to be distributed to the pixel at the coordinates (x−1, y) for correction is obtained.

The area of the portion remaining in the pixel at the coordinates (x, y) is (1−Δx″)×(1−Δy″). From this value, the beam modulation rate for the pixel at the coordinates (x, y) is obtained.

As described above, for each pixel, the beam modulation rate for the pixel and the beam modulation rate for at least one surrounding pixel to be a distribution destination are calculated. The correction map generation unit 51 then generates and outputs a modulation rate map (correction map) in which modulation rates are defined for a writing region to be written by multiple beams such that the calculated beam modulation rate for the pixel is defined at the position of the pixel, and the calculated beam modulation rate for the at least one surrounding pixel to be a distribution destination in the vicinity of the pixel is associated with the pixel and defined at the position of the at least one surrounding pixel to be a distribution destination in the vicinity of the pixel.

In the correction process (S5), the correction map (modulation rate map) generated in the correction map generation process (S4) is applied to the irradiation doses for the respective pixels calculated in the shot data generation process (S2) to obtain corrected irradiation doses. Specifically, the irradiation dose correction unit 54 calculates a corrected irradiation dose for each pixel. The corrected irradiation dose for each pixel is obtained by adding the value obtained by multiplying the beam modulation rate for the pixel defined in the modulation rate map by the beam irradiation dose for the pixel and the value obtained by multiplying the beam modulation rate for at least one pixel (surrounding pixel), which is defined at the position of the pixel as at least one surrounding pixel associated for distribution in the modulation rate map, by the beam irradiation dose for a pixel serving as an associated destination of the at least one pixel. As the corrected irradiation dose calculation method, methods described in Japanese Unexamined Patent Application Publication No. 2016-119423 and other publications can be used.

In this case, it is suitable if the corrected irradiation dose is the irradiation dose corrected using the irradiation dose for the dimensional variation for phenomena causing dimensional variation, such as proximity effect, overshadowing effect, and loading effect.

The corrected irradiation dose for each pixel is defined in a corrected irradiation dose map and stored in the memory device 142.

In the writing process (S6), the writing unit 150 writes a pattern on the sample 101 using multiple beams such that corresponding pixels are irradiated with beams with the corrected irradiation doses in a respective manner. First, the data processing unit 61 converts the corrected irradiation doses into irradiation times and then sorts the irradiation times in shot order according to the writing sequence. The sorted irradiation time array data is then output to the deflection control circuit 130.

The deflection control circuit 130 outputs, for each shot, the irradiation time array data to the blanking aperture array substrate 204. Then, for each shot of each beam, the writing unit 150 performs writing for the corresponding irradiation time under the control performed by the writing control unit 60.

In the present embodiment, the modulation rates (beam distribution amounts to surrounding pixels) are determined by considering not only the amounts of beam displacement but also the centroid positions of the patterns within the pixels. Thus, the amount of unnecessary distribution can be reduced, and the degradation of resolution can be suppressed.

In the embodiment described above, the example has been described in which the centroid position of the pattern within a pixel is calculated from its beam irradiation dose; however, centroid positions based on the states of adjacent pixels may be listed in a table in advance, and the modulation rates (beam distribution amounts to surrounding pixels) may be obtained by referring to the table. When the shot data generation unit 53 calculates, for each pixel, the area density of the pattern placed inside the pixel, the centroid position may be calculated and the data of the centroid position may be stored in the storage unit.

In the embodiment described above, the example has been described in which the amount of beam displacement is shifted on the basis of the centroid position of the pattern within a pixel; however, the amount of beam displacement may be shifted on the basis of the size (shape) or edge positions of the pattern within a pixel.

For example, the correction map generation unit 51 obtains, for each pixel, a size L′ₓ in the x-direction and a size L′_{y} in the y-direction of the pattern within the pixel using a pixel size Lₓ in the x-direction, a pixel size L_{y} in the y-direction, and the beam irradiation dose d for the pixel. For example, the sizes L′ₓ and L′_{y} can be obtained by L′ₓ=dₓLₓ, and L′_{y}=d_{y}L_{y}. The method for calculating, from the beam irradiation dose d for each pixel, the size of the pattern in the pixel is not limited to this, and other calculation methods, such as approximating dₓ=d_{y}=√_{d}, may be used to determine the sizes of the patterns within pixels.

Note that in a case where each of the x-direction size Lₓ and y-direction size L_{y} of pixels is set to 1, since the beam irradiation doses d are within the range of 0≤d≤1, the x-direction size L′ₓ and y-direction size L′_{y} of the patterns within the pixels are also within the ranges of 0≤L′ₓ≤1 and 0≤L′_{y}≤1.

The correction map generation unit 51 calculates the area that overlaps with surrounding pixels in a case where the pattern, whose size is calculated through the above-described calculation, is displaced by the amount of displacement defined in the displacement data.

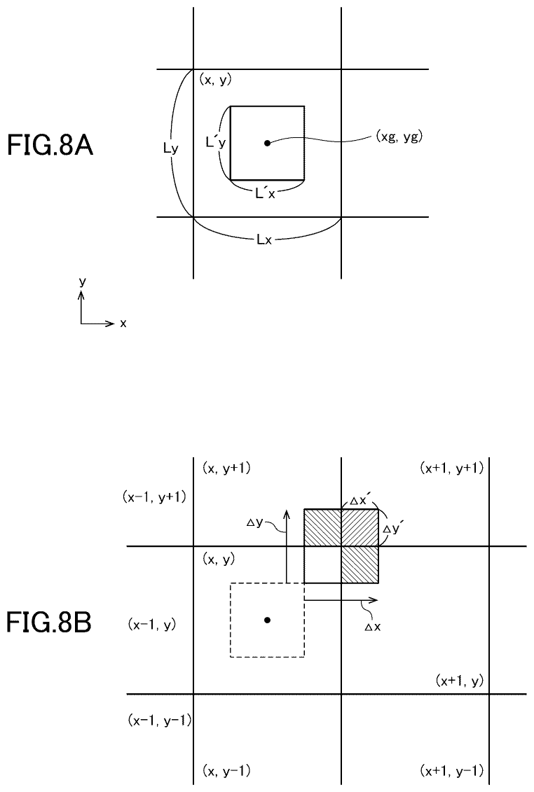

For example, in a case where the graphic pattern is placed as illustrated in FIG. 6A, the pattern within the pixel at the coordinates (x, y) obtained through the above-described calculation is as illustrated in FIG. 8A. The shape of the pattern within the pixel is obtained from the x-direction size L′ₓ and y-direction size L′_{y} of the pattern within the pixel, and the edge positions of the pattern within the pixel are determined from this shape and the pixel center position (x_{g}, y_{g}). Similar to the example in FIG. 5 and the example in FIG. 6B, FIG. 8B illustrates a case where a beam emitted toward the pixel at the coordinates (x, y) is displaced by Δx in the x-direction and Δy in the y-direction.

The correction map generation unit 51 calculates the amounts of displacement Δx′ and Δy′ from the following equations. The amount of displacement Δx′ corresponds to the amount by which the pattern in the pixel at the coordinates (x, y) protrudes in the x-direction from the pixel at the coordinates (x, y). The amount of displacement Δy′ corresponds to the amount by which the pattern in the pixel at the coordinates (x, y) protrudes in the y-direction from the pixel at the coordinates (x, y).

$$Δ {x}^{′} = \frac{Δ x - \frac{1 - {L}_{x}^{′}}{2}}{{L}_{x}^{′}}$$

$$Δ {y}^{′} = \frac{Δ y - \frac{1 - {L}_{y}^{′}}{2}}{{L}_{y}^{′}}$$

The correction map generation unit 51 uses the following limiter to perform processing such that the amounts of displacement Δx′ and Δy′ are to be smaller than the amounts of beam displacement Δx″ and Δy″ having geometrically valid values.

$$Δ {x}^{′′} = min ( max ( Δ {x}^{′} , 0 ) , 1 )$$

$$Δ {y}^{′′} = min ( max ( Δ {y}^{′} , 0 ) , 1 )$$

Similar to the example in FIG. 7, the correction map generation unit 51 uses the amounts of beam displacement Δx″ and Δy″ to calculate beam irradiation doses (modulation rates) to be distributed to surrounding pixels. Note that the amount of distribution to each pixel is the same as in the example in FIG. 7, and thus the description will be omitted here.

In this manner, the modulation rates (beam distribution amounts to surrounding pixels) are determined by considering not only the amounts of beam displacement but also the shapes (sizes) of the patterns within the pixels. As a result, the amount of unnecessary distribution can be reduced, and the degradation of resolution can be suppressed.

Pattern shapes based on the states of adjacent pixels may be listed in a table in advance, and the modulation rates (beam distribution amounts to surrounding pixels) may be obtained by referring to the table. Moreover, when the shot data generation unit 53 calculates, for each pixel, the area density of the pattern placed inside the pixel, the pattern shape within the pixel may be detected and stored in the storage unit.

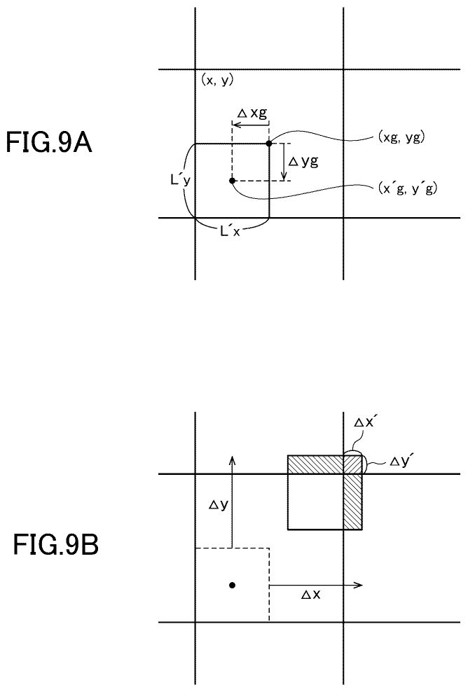

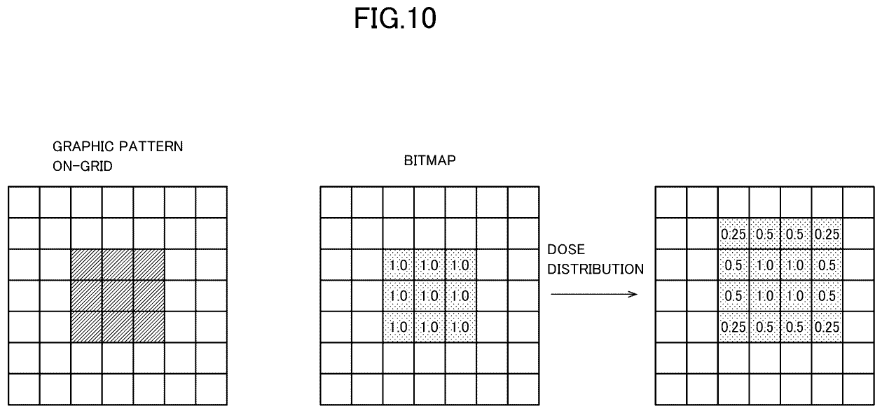

The modulation rate may be determined by considering both the centroid position and the shape of the pattern in the pixel. For example, as illustrated in FIG. 9A, the correction map generation unit 51 uses a similar method to that described above to calculate, for the pixel at the coordinates (x, y), the amount of displacement of the centroid position in the x-direction, Δx_{g}, and the amount of displacement of the centroid position in the y-direction, Δy_{g}, for the centroid position (x′_{g}, y′_{g}) of the pattern within the pixel when viewed from the pixel center (x_{g}, y_{g}).

Moreover, the correction map generation unit 51 uses a similar method to that described above to obtain the x-direction size L′ₓ and the y-direction size L′_{y} of the pattern in the pixel.

Similar to FIGS. 5, 6B, and 8B, FIG. 9B illustrates a case where a beam emitted toward the pixel at the coordinates (x, y) is displaced by Δx in the x-direction and Δy in the y-direction. The correction map generation unit 51 calculates the amounts of displacement Δx′ and Δy′ from the following equations. The amount of displacement Δx′ corresponds to the amount by which the pattern in the pixel at the coordinates (x, y) protrudes in the x-direction from the pixel at the coordinates (x, y). The amount of displacement Δy′ corresponds to the amount by which the pattern in the pixel at the coordinates (x, y) protrudes in the y-direction from the pixel at the coordinates (x, y).

$$Δ {x}^{′} = \frac{( Δ x + Δ {x}_{g} - \frac{1 - {L}_{x}^{′}}{2} )}{{L}_{x}^{′}} \qquad {L}_{x}^{′} = ( 1 - 2 \vert Δ {x}_{g} \vert ) \qquad Δ {x}^{′} = \frac{( Δ x + Δ {x}_{g} - \vert Δ {x}_{g} \vert )}{( 1 - 2 \vert Δ {x}_{g} \vert )}$$

$$Δ {y}^{′} = \frac{( Δ y + Δ {y}_{g} - \frac{1 - {L}_{y}^{′}}{2} )}{{L}_{y}^{′}} \qquad {L}_{y}^{′} = ( 1 - 2 \vert Δ {y}_{g} \vert ) \qquad Δ {y}^{′} = \frac{( Δ y + Δ {y}_{g} - \vert Δ {y}_{g} \vert )}{( 1 - 2 \vert Δ {y}_{g} \vert )}$$

Furthermore, the correction map generation unit 51 uses the following limiter to calculate, from the amounts of displacement Δx′ and Δy′, the amounts of displacement Δx″ and Δy″ that are geometrically valid. The amounts of distribution to surrounding pixels (beam modulation rates) are obtained using these amounts of displacement Δx″ and Δy″.

Similar to the example in FIG. 7, the correction map generation unit 51 uses the amounts of beam displacement Δx″ and Δy″ to calculate beam irradiation doses (modulation rates) to be distributed to surrounding pixels. Note that the amount of distribution to each pixel is the same as in the example in FIG. 7, and thus the description will be omitted here.

By determining the modulation rate considering both the centroid position and the shape of the pattern in the pixel, the degradation of resolution can be suppressed even more effectively.

In the embodiment described above, the examples have been described in which the beam irradiation dose for each pixel is used to calculate the centroid position and the shape of the pattern within the pixel; however, the centroid position and the shape of the pattern within the pixel may also be obtained from the edge positions of the pattern within the pixel. For example, the x-directional size of the pattern within the pixel is obtained from the right edge position and left edge position of the pattern within the pixel. The y-directional size of the pattern within the pixel is obtained from the top edge position and bottom edge position of the pattern within the pixel. The shape of the pattern within the pixel is obtained from the x-directional size and y-directional size of the pattern within the pixel. Moreover, the centroid position of the pattern within the pixel is obtained from the top, bottom, left, and right edge positions. Using these values, the beam irradiation doses (modulation rates) to be distributed to surrounding pixels can be calculated in the same manner as above.

Part of the calculations performed by the correction map generation unit 51 described above may be performed by a device external to the writing apparatus 100 and the results of the calculations may be input to the control computer 110.

In the embodiment, the configuration has been described where an electron beam is used as an example of a charged particle beam. However, the charged particle beam is not limited to an electron beam, and may be a beam using a charged particle beam, such as an ion beam.

The above embodiment describes a writing apparatus that writes a pattern on a substrate, but it can be applied to other irradiation apparatus that irradiates a beam onto an object, such as an inspection apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multiple charged-particle beam irradiation apparatus comprising:
a correction map generation unit that calculates, for each pixel serving as an irradiation unit region per beam of multiple charge-particle beams, a beam modulation rate for the pixel and a beam modulation rate for at least one of pixels surrounding the pixel, based on an amount of displacement of a beam emitted toward the pixel and a position of a pattern placed within the pixel to correct, by modulating a beam irradiation dose for the pixel and a beam irradiation dose for the at least one of the pixels surrounding the pixel, a displacement of a pattern formed by a beam that is emitted toward the pixel but displaced, and generates a correction map in which modulation rates are defined for an irradiation region to be irradiated with multiple charge-particle beams such that the calculated beam modulation rate for the pixel is defined at a position of the pixel, and the beam modulation rate for the at least one of the pixels surrounding the pixel is associated with the pixel and defined at a position of the at least one of the pixels surrounding the pixel;
a shot data generation unit that calculates, for each pixel, a beam irradiation dose for the pixel;
an irradiation dose correction unit that calculates, for each pixel, a corrected irradiation dose by adding a value obtained by multiplying the beam modulation rate for the pixel defined in the correction map by the beam irradiation dose for the pixel and a value obtained by multiplying the beam modulation rate for the at least one pixel, which is defined at the position of the pixel as the at least one of the surrounding pixels in the correction map, by a beam irradiation dose for a pixel serving as an associated destination of the at least one pixel; and
an irradiation unit that irradiates a sample surface with multiple charged-particle beams such that corresponding pixels are irradiated with beams with the corrected irradiation doses in a respective manner.

2. The multiple charged-particle beam irradiation apparatus according to claim 1, wherein the correction map generation unit calculates the beam modulation rate for the pixel and the beam modulation rate for the at least one of the pixels surrounding the pixel, based on the amount of displacement of the beam emitted toward the pixel and a centroid position of the pattern placed within the pixel.

3. The multiple charged-particle beam irradiation apparatus according to claim 2, wherein the correction map generation unit uses the beam irradiation dose for the pixel to calculate the centroid position of the pattern placed within the pixel.

4. The multiple charged-particle beam irradiation apparatus according to claim 1, wherein the correction map generation unit calculates the beam modulation rate for the pixel and the beam modulation rate for the at least one of the pixels surrounding the pixel, based on the amount of displacement of the beam emitted toward the pixel and an edge position of the pattern placed within the pixel.

5. The multiple charged-particle beam irradiation apparatus according to claim 4, wherein the correction map generation unit uses the beam irradiation dose for the pixel to calculate the edge position of the pattern placed within the pixel.

6. The multiple charged-particle beam irradiation apparatus according to claim 1, wherein the correction map generation unit calculates the beam modulation rate for the pixel and the beam modulation rate for the at least one of the pixels surrounding the pixel, based on the amount of displacement of the beam emitted toward the pixel and a centroid position and a shape of the pattern placed within the pixel.

7. The multiple charged-particle beam irradiation apparatus according to claim 1, wherein the correction map generation unit includes a limiter that performs processing such that the beam modulation rate for the pixel and the beam modulation rate for the at least one of the pixels surrounding the pixel fall within a predetermined range.

8. A multiple charged-particle beam irradiation method comprising:
calculating, for each pixel serving as an irradiation unit region per beam of multiple charge-particle beams, a beam modulation rate for the pixel and a beam modulation rate for at least one of pixels surrounding the pixel, based on an amount of displacement of a beam emitted toward the pixel and a position of a pattern placed within the pixel to correct, by modulating a beam irradiation dose for the pixel and a beam irradiation dose for the at least one of the pixels surrounding the pixel, a displacement of a pattern formed by a beam that is emitted toward the pixel but displaced;
generating a correction map in which modulation rates are defined for an irradiation region to be irradiated with multiple charge-particle beams such that, for each pixel, the calculated beam modulation rate for the pixel is defined at a position of the pixel, and the calculated beam modulation rate for the at least one of the pixels surrounding the pixel is associated with the pixel and defined at a position of the at least one of the pixels surrounding the pixel;
calculating, for each pixel, a beam irradiation dose for the pixel;
calculating, for each pixel, a corrected irradiation dose by adding a value obtained by multiplying the beam modulation rate for the pixel defined in the correction map by the beam irradiation dose for the pixel and a value obtained by multiplying the beam modulation rate for the at least one pixel, which is defined at the position of the pixel as the at least one of the surrounding pixels in the correction map, by a beam irradiation dose for a pixel serving as an associated destination of the at least one pixel; and
irradiating a sample surface with multiple charged-particle beams such that corresponding pixels are irradiated with beams with the corrected irradiation doses in a respective manner.

9. A correction map generation apparatus that calculates, for each pixel serving as an irradiation unit region per beam of multiple charge-particle beams, a beam modulation rate for the pixel and a beam modulation rate for at least one of pixels surrounding the pixel, based on an amount of displacement of a beam emitted toward the pixel and a position of a pattern placed within the pixel to correct, by modulating a beam irradiation dose for the pixel and a beam irradiation dose for the at least one of the pixels surrounding the pixel, a displacement of a pattern formed by a beam that is emitted toward the pixel but displaced, and generates and outputs a correction map in which modulation rates are defined for an irradiation region to be irradiated with multiple charge-particle beams such that the calculated beam modulation rate for the pixel is defined at a position of the pixel, and the beam modulation rate for the at least one of the pixels surrounding the pixel is associated with the pixel and defined at a position of the at least one of the pixels surrounding the pixel.

10. A correction map generation method comprising:
calculating, for each pixel serving as an irradiation unit region per beam of multiple charge-particle beams, a beam modulation rate for the pixel and a beam modulation rate for at least one of pixels surrounding the pixel, based on an amount of displacement of a beam emitted toward the pixel and a position of a pattern placed within the pixel to correct, by modulating a beam irradiation dose for the pixel and a beam irradiation dose for the at least one of the pixels surrounding the pixel, a displacement of a pattern formed by a beam that is emitted toward the pixel but displaced; and
generating and outputting a correction map in which modulation rates are defined for an irradiation region to be irradiated with multiple charge-particle beams such that, for each pixel, the calculated beam modulation rate for the pixel is defined at a position of the pixel and the calculated beam modulation rate for the at least one of the pixels surrounding the pixel is associated with the pixel and defined at a position of the at least one of the pixels surrounding the pixel.
